(19) United States
(12) Patent Application Publication
(10) Pub. No.: US 2004/0087138 A1
(43) Pub. Date: May 6, 2004

(54) Method for manufacturing buried wiring structure

(75) Inventors: Takeo Ishibashi, Tokyo (JP); Yoshiharu Ono, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/619,433

(22) Filed: Jul. 16, 2003

(30) Foreign Application Priority Data
Oct. 22, 2002 (JP) 2002-307459

(51) Int. Cl. H01L 21/4763

(52) U.S. Cl. 438/633; 438/630

(57) ABSTRACT

A first depressed portion is formed on an insulating film. A burying material is applied onto the first depressed portion and the insulating film to bury the first depressed portion. Chemical mechanical polishing of the burying material is performed until the insulating film is exposed, thereby leaving the burying material only in the first depressed portion. A resist having a pattern of a second depressed portion that overlaps the first depressed portion is formed on the insulating film in which the burying material has been buried. The burying material and the insulating film are etched to a predetermined depth using the resist as a mask to form the second depressed portion. The resist and the burying material left are removed after the step of etching. A conductive material is deposited in the first depressed portion and the second depressed portion.

### BACKGROUND OF THE INVENTION

1. Field of the Invention

The present invention relates to a method for manufacturing buried wiring structure by forming a first depressed portion on an insulating film, forming a second depressed portion over lapping the first depressed portion, and depositing a conductive material in the first and second depressed portions.

2. Background Art

With the recent high integration and speed increase of semiconductor devices or the like, the reduction of the resistance of wiring materials has become essential. Although various materials are available as the wiring materials, some wiring materials are difficult to process by dry etching. Therefore, a process by depositing an insulating film on an under-layer wiring, forming contact holes and wiring channels in the insulating film, and depositing a conductive material in the contact holes and wiring channels has been adopted.

In such a conventional process, an insulating film having a pattern of contact holes is deposited on an under-layer wiring; a resist is formed on the insulating film using a lithography technique; the insulating film is etched using the resist as a mask to form contact holes, which are first depressed portions; and the resist is removed. Then, a filling material is applied onto the contact holes and the insulating film to fill the contact holes. Here, an organic polymeric material that contains an aromatic compound functioning as an antireflective film is used as a filling material.

Next, the filling material is subject to overall etching, such as reactive ion etching and ashing in oxygen plasma, to leave the burying material only in the contact holes. Then, a resist having a pattern of wiring channels that overlap the contact holes is formed on the insulating film wherein the burying material is buried using a photolithography technique, and the burying material and the insulating film is etched to a predetermined depth using the resist as a mask to form wiring channels, which is second depressed portions. At this time, since the under-layer wirings on the bottoms of the contact holes are covered with the burying material, etching does not damage the under-layer wirings. Furthermore, the resist and the burying material remaining after etching are removed to expose the under-layer wirings on the bottoms of the contact holes. Then, a conductive material is deposited in the contact holes and the wiring channels to form wirings in contact with the under-layer wirings (refer to e.g., Japanese Patent Laid-Open No. 8-335634 (p. 4, FIG. 1)).

When the contact holes are filled with the burying material, the quantity and the shape of the burying material in each contact hole depend on the density of the pattern for the contact holes. In a location where the pattern is dense, the quantity of the burying material buried in the contact holes decreases, and the margin for preventing the damage to under-layer wirings is reduced. If a larger quantity of the burying material is applied to bury all the contact holes completely, the film of the burying material formed on the insulating film becomes the film subject to etching, and if etching is performed in this state, the etching resistance of the resist acting as an etching mask becomes insufficient.

If the film of the burying material on the insulating film is removed by overall etching, such as reactive ion etching and ashing in oxygen plasma, it is difficult to planarize the upper surfaces of the burying material in the contact holes and the insulating film in the same level. There has been a problem in that even when the pattern for wiring channels overlaps the pattern for the contact holes, the pattern for highly accurate wiring channels cannot be formed, because the surface of the insulating film in this area cannot be planarized.

Conventionally, an organic polymeric material functioning as an antireflective film has been used as the burying material. However, since this material contains aromatic compounds that absorb the light of wavelengths used in photolithography, the material is cured, and the etching rate thereof becomes smaller than the etching rate of the insulating film. Consequently, the etching of the burying material buried in the contact holes is delayed, in etching for forming the wiring channel pattern, and the surrounding insulating film remains not etched. Therefore, there has been a problem of forming a fence-like etching residue on the edges of the contact holes after removing the burying material.

### SUMMARY OF THE INVENTION

The present invention is achieved to solve the above-described problems. A first object of the present invention is to provide a method for manufacturing a buried wiring structure wherein first depressed portions are formed in an insulating film, and when second depressed portions that over lap the first depressed portions are formed, an accurate pattern for the second depressed portions can be formed. A second object of the present invention is to provide a method for manufacturing a buried wiring structure that can prevent the occurrence of etching residues on the edges of the contact holes.

According to one aspect of the present invention, a first depressed portion is formed on an insulating film. A burying material is applied onto the first depressed portion and the insulating film to bury the first depressed portion. Chemical mechanical polishing of the burying material is performed until the insulating film is exposed, thereby leaving the burying material only in the first depressed portion. A resist having a pattern of a second depressed portion that overlaps the first depressed portion is formed on the insulating film in which the burying material has been buried. The burying material and the insulating film are etched to a predetermined depth using the resist as a mask to form the second depressed portion. The resist and the burying material left are removed after the step of etching. A conductive material is deposited in the first depressed portion and the second depressed portion.

Other and further objects, features and advantages of the invention will appear more fully from the following description.

### BRIEF DESCRIPTION OF THE DRAWINGS

FIG. 1 shows a method for manufacturing a buried wiring structure according to the first embodiment of the present invention.

FIG. 2 shows a method for manufacturing a buried wiring structure according to the second embodiment of the present invention.

### DETAILED DESCRIPTION OF THE PREFERRED EMBODIMENTS

Embodiment

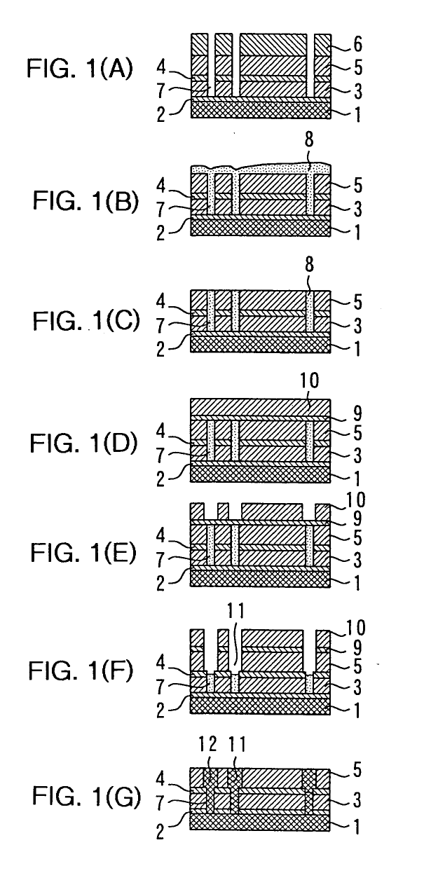

FIG. 1 shows a method for manufacturing a buried wiring structure according to the first embodiment of the present invention.

First, as shown in FIG. 1(A), a protecting film 2, an insulating film 3, an etching stopper film 4, and an insulating film 5 are deposited in sequence on an under-layer wiring 1 consisting of Cu or the like. A resist 6 having a pattern of contact hole 7 is formed on the insulating film 5. Since the upper surface of the resist 6 is planar, this pattern is formed in high accuracy using photolithography. Then, the insulating film 5, the etching stopper film 4, and the insulating film 3 are etched using the resist 6 as a mask to form contact holes 7 as a first depressed portion. During this etching, the under-layer wiring 1 is protected by the protecting film 2.

Next, as shown in FIG. 1(B), the resist 6 is removed, a burying material 8 is applied onto the contact holes 7 and the insulating film 5 by spin coating or the like, and undergone baking (heat treatment) at 180 to 220° C. for about 60 seconds to evaporate the solvents in the materials. At this time, the film thickness of the burying material 8 on the insulating film 5 is preferably about 50 to 1,500 nm. Here, an organic polymeric material having a low molecular weight is used as the burying material 8, which has a high fluidity when heat-treated. Therefore, regardless of the density of the pattern, the contact holes 7 are completely filled with the burying material 8. The organic polymeric material used as the burying material 8 contains no aromatic compounds, and has substantially the same etching rate as the etching rate of the insulating film 5. It is also preferable that the burying material 8 is a material having a high thermosetting temperature. An example of such burying materials 8 is the mixture of an acrylic polymer having a weight average molecular weight of 4,000, a cross-linking agent having alkoxymethylamino groups, and a sulfonic acid-based acidic catalyst, dissolved with an acetate-based solvent.

Next, as shown in FIG. 1(C), the burying material 8 is polished by chemical mechanical polishing using colloidal silica or the like as the slurry until the insulating film 5 is exposed, so as to leave the burying material 8 only in the contact holes 7. At this time, the upper surfaces of the burying material 8 in the contact holes 7 and the insulating film 5 are aligned and planarized.

Next, as shown in FIG. 1(D), an antireflective film 9 is formed on the insulating film 5 wherein the burying material 8 has been buried. The antireflective film 9 is composed of an organic material, and has the ability to absorb exposure wavelength used when the resist pattern is formed in the later process. The thickness of the antireflective film 9 is preferably about 50 to 1,500 nm. The burying material 8 and the antireflective film 9 are not miscible to each other. A resist 10 is formed on the antireflective film 9. The thickness of the resist 10 is preferably about 500 to 1,500 nm. The resist 10 can be applied using spin coating or the like, and undergone baking (heat treatment) at, for example, 80 to 150° C. for about 60 seconds to evaporate the solvents in the material.

Then, in order to form the resist pattern for the wiring channel 11 (refer to FIG. 1(F)) that overlaps the contact holes 7 as shown in FIG. 1(E), the resist 10 is exposed using i-beams or a light source corresponding to the resist sensitive wavelength, such as KrF excimer and ArF excimer. Here, since the upper surface of the insulating film 5 has been planarized, the upper surface of the resist 10 is flat, and the pattern for the wiring channel 11 is exposed accurately. After exposure, PEB (post-exposure baking) is performed at, for example, 80 to 120° C. for about 60 seconds to improve the resolution of the resist 10, and development is performed using a 2.00 to 2.50% aqueous solution of an alkali, such as TMAH (tetramethyl ammonium hydroxide). Thereafter, PDB (post development baking) is performed at, for example, 100 to 130° C. for about 60 seconds to cure the resist 10 as required (FIG. 1(e)).

Next, as shown in FIG. 1(F), the antireflective film 9, the insulating film 5, and the burying material 8 are etched to a predetermined depth using the resist 10 as a mask to form a wiring channel 11, which is a second depressed portion. At this time, the insulating film 5 and the burying material 8 are etched at substantially the same rate. This etching may be performed at once, or may be divided into two steps: first the antireflective film 9, and then the insulating film 5 and the burying material 8. In any case, since the etching-stopper film 4 is present during etching, the insulating film 3 under the etching-stopper film 4 is not etched. Next, the etching-stopper film 4 on the bottom of the wiring channel 11 is removed.

Next, as shown in FIG. 1(G), the resist 10 and the burying material 8 remaining after etching are removed, and the protecting film 2 on the bottom of the contact holes 7 is removed. Then a conductive material such as Cu is deposited on the contact holes 7 and the wiring channel 11 to complete a buried wiring 12.

According to the manufacturing method as described above, when a first depressed portion (contact hole 7) is formed on the insulating films (2 to 5), and a second depressed portion (wiring channel 11) overlapping the first depressed portion is formed, a highly accurate second depressed portion can be formed. The occurrence of etching residues on the edge of the contact holes 7 can also be prevented. Thereby, a two-layer wiring structure wherein the buried wiring 12 is electrically connected to the under-layer wiring 1 with the conductive material filled in the contact hole 7 can be formed in high accuracy.

Second Embodiment

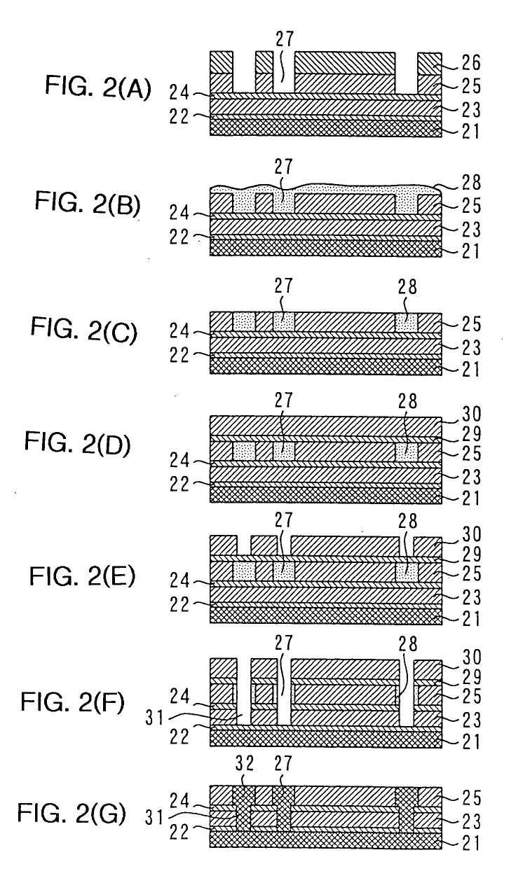

FIG. 2 shows a method for manufacturing a buried wiring structure according to the second embodiment of the present invention.

First, as shown in FIG. 2(A), a protecting film 22, an insulating film 23, an etching stopper film 24, and an insulating film 25 are deposited in sequence on an under-layer wiring 21 consisting of Cu or the like. A resist 26 having a pattern of wiring channel 27 is formed on the insulating film 25. Since the upper surface of the resist 26 is planar, this pattern is formed in high accuracy using photolithography. Then, the insulating film 25 is etched using the resist 26 as a mask to form a wiring channel 27, which is a first depressed portion. Since the etching-stopper film 24 is present during etching, the insulating film 23 under the etching-stopper film 24 is not etched.

Next, as shown in FIG. 2(B), the resist 26 is removed, a burying material 28 is applied onto the wiring channels 27 and the insulating film 25 by spin coating or the like, and undergone baking (heat treatment) at 180 to 220° C. for about 60 seconds to evaporate the solvents in the materials. At this time, the film thickness of the burying material 28 on the insulating film 25 is preferably about 50 to 1,500 nm. Here, an organic polymeric material having a low molecular weight is used as the burying material 28, which has a high fluidity when heat-treated. Therefore, regardless of the density of the pattern, the wiring channels 27 are completely filled with the burying material 28. The organic polymeric material used as the burying material 28 containing no aromatic compounds are advantageous, because the etching rate becomes higher when the burying material 28 is etched later. It is also preferable that the burying material 28 is a material having a high thermosetting temperature. An example of such burying materials 28 is the mixture of an acrylic polymer having a weight average molecular weight of 4,000, across-linking agent having alkoxymethylamino groups, and a sulfonic acid-based acidic catalyst, dissolved with an acetate-based solvent.

Next, as shown in FIG. 2(C), the burying material 28 is polished by chemical mechanical polishing using colloidal silica or the like as the slurry until the insulating film 25 is exposed, so as to leave the burying material 28 only in the wiring channels 27. At this time, the upper surfaces of the burying material 28 in the wiring channels 27 and the insulating film 25 are aligned and planarized.

Next, as shown in FIG. 2(D), an antireflective film 29 is formed on the insulating film 25 wherein the burying material 28 has been buried. The antireflective film 29 is composed of an organic material, and has the ability to absorb exposure wavelength used when the resist pattern is formed in the later process. The thickness of the antireflective film 29 is preferably about 50 to 1,500 nm. The burying material 28 and the antireflective film 29 are not miscible to each other. A resist 30 is formed on the antireflective film 29. The thickness of the resist 30 is preferably about 500 to 1,500 nm. The resist 30 can be applied by using spin coating or the like, and undergone baking (heat treatment) at, for example, 80 to 150° C. for about 60 seconds to evaporate the solvents in the material.

Then, as shown in FIG. 2(E), in order to form the resist pattern for a contact hole 31 (refer to FIG. 2(F)) that overlaps the wiring channels 27, the resist 30 is exposed using i-beams or a light source corresponding to the resist sensitive wavelength, such as KrF excimer and ArF excimer. Here, since the upper surface of the insulating film 25 has been planarized, the upper surface of the resist 30 is flat, and the pattern for the contact hole 31 is exposed accurately. After exposure, PEB (post-exposure baking) is performed at, for example, 80 to 120° C. for about 60 seconds to improve the resolution of the resist 30, and development is performed by using a 2.00 to 2.50% aqueous solution of an alkali, such as TMAH (tetramethyl ammonium hydroxide). Thereafter, PDB (post development baking) is performed at, for example, 100 to 130° C. for about 60 seconds to cure the resist 30 as required.

Next, as shown in FIG. 2(F), the antireflective film 29, the insulating film 23, and the burying material 28 are etched to a predetermined depth using the resist 30 as a mask to form a contact hole 31, which is a second depressed portion. During this etching the under-layer wiring 21 is protected by the protecting film 22.

Next, as shown in FIG. 2(G), the resist 30 and the burying material 28 remaining after etching are removed, and the protecting film 22 on the bottom of the contact hole 31 is also removed. Then a conductive material such as Cu is deposited on the wiring channels 27 and the contact hole 31 to complete a buried wiring 32.

According to the manufacturing method as described above, when first depressed portions (wiring channels 27) are formed on the insulating films (22 to 25), and a second depressed portion (contact hole 31) overlapping the first depressed portions is formed, a highly accurate second depressed portion can be formed. The occurrence of etching residues on the edge of the contact hole 31 can also be prevented. Thereby, a two-layer wiring structure wherein the buried wiring 32 is electrically connected to the under-layer wiring 21 with the conductive material filled in the contact hole 31 can be formed in high accuracy.

Although examples of wiring structures in semiconductor devices have been described above, the wiring structure of the present invention can be applied not only to semiconductor devices, but also to other electronic devices, such as liquid crystal display devices and magnetic memories. Therefore, the present invention can be translated as a method for manufacturing electronic devices, such as semiconductor devices and liquid crystal display devices.

The features and advantages of the present invention may be summarized as follows.

As described above, when a first depressed portion is formed on an insulating film, and a second depressed portion overlapping the first depressed portion is formed, a highly accurate second depressed portion can be formed.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-307459 filed on Oct. 22, 2002 including specification, claims, drawings and summary, on which the Convention priority of the present application is based, are incorporated herein by reference in its entirety.

What is claimed is:

1. A method for manufacturing buried wiring structure comprising the steps of:
forming a first depressed portion on an insulating film;
applying a burying material on said first depressed portion and said insulating film to bury said first depressed portion;
performing chemical mechanical polishing of said burying material until the insulating film is exposed, thereby leaving the burying material in said first depressed portion;
forming a resist having a pattern of a second depressed portion that overlaps said first depressed portion on said insulating film wherein said burying material has been buried;
etching said burying material and said insulating film to a predetermined depth using the resist as a mask to form the second depressed portion;
removing said resist and said burying material left after the step of etching; and
depositing a conductive material in said first depressed portion and said second depressed portion.

2. A method for manufacturing buried wiring structure comprising the steps of:
depositing an insulating film on under-layer wiring;
forming a contact hole in said insulating film;
applying a burying material on said contact hole and said insulating film to bury said contact hole;
performing chemical mechanical polishing of said burying material until the insulating film is exposed, thereby leaving the burying material in said contact hole;
forming a resist having a pattern of a wiring channel that overlaps said contact hole on said insulating film wherein said burying material has been buried;
etching said burying material and said insulating film to a predetermined depth using the resist as a mask to form the wiring channel;
removing said resist and said burying material left after the step of etching; and
depositing a conductive material in said contact hole and said wiring channel.

3. A method for manufacturing buried wiring structure comprising the steps of:
depositing an insulating film on under-layer wiring;
forming a wiring channel in said insulating film;
applying a burying material on said wiring channel and said insulating film to bury said wiring channel;
performing chemical mechanical polishing of said burying material until the insulating film is exposed, thereby leaving the burying material in said wiring channel;
forming a resist having a pattern of a contact hole that overlaps said wiring channel on said insulating film wherein said burying material has been buried;
etching said burying material and said insulating film using the resist as a mask to form the contact hole;
removing said resist and said burying material left after the step of etching; and
depositing a conductive material in said contact hole and said wiring channel.

4. The method for manufacturing buried wiring structure according to claim 2, wherein an organic polymeric material having substantially the same etching rate as the etching rate of said insulating film is used as said burying material.

5. The method for manufacturing buried wiring structure according to claim 1, wherein an organic polymeric material containing no aromatic compounds is used as said burying material.

6. The method for manufacturing buried wiring structure according to claim 5, further comprising a step for forming an antireflective film on said insulating film prior to the step of forming said resist.

7. The method for manufacturing buried wiring structure according to claim 6, wherein said burying material and said antireflective film are not soluble to each other.
